(19) United States
(12) Patent Application Publication
(10) Pub. No.: US 2021/0049791 A1
(43) Pub. Date: Feb. 18, 2021

(54) METHOD AND APPARATUS FOR RECONSTRUCTING A SIGNAL CAPTURED BY A SNAPSHOT COMPRESSIVE SENSING SYSTEM

(71) Applicant: NOKIA TECHNOLOGIES OY, Espoo (FI)

(72) Inventors: Xin YUAN, New Providence, NJ (US); Shirin JALALI, Weehawken, NJ (US)

(21) Appl. No.: 17/041,934

(22) PCT Filed: Mar. 28, 2019
(86) PCT No.: PCT/FI2019/050252

§ 371 Date: Sep. 25, 2020

Related U.S. Application Data
(60) Provisional application No. 62/649,972, filed on Mar. 29, 2018.

(51) Int. Cl. G06T 9/00; H03M 7/30; G06T 11/00; G06T 7/00

(52) U.S. Cl. CPC G06T 9/00; H03M 7/3062; G06T 11/006; G06T 2211/424; G06T 7/0002; G06T 2207/10101; G06T 11/005

(57) ABSTRACT

A method is provided for decompressing images captured by a compressive imaging system in conjunction with a compressive imaging application. The method comprises determining an estimation error e^{t} based on a difference between: (i) a measurement y captured by the compressive imaging system and (ii) a product of a sensing matrix H and a signal x^{t} that has been estimated. The method comprises determining a gradient descent st+1 based on a sum of: (i) the signal x^{t} that has been estimated and (ii) a product of a step size μ, a vector formulation of the sensing matrix H^{T} and the estimation error e^{t}. The method comprises projecting the gradient descent s^{t+1} comprising applying a compression function f and a decompression function g to estimate the signal x^{t+1}. The method comprises iteratively repeating determining the estimation error e^{t}; determining the gradient descent s^{t+1} and projecting the gradient descent s^{t+1} to provide a reconstructed signal following a final iteration; and providing the reconstructed signal for display or storage.

### TECHNOLOGICAL FIELD

An example embodiment relates generally to compressive sensing and, more particularly, to snapshot compressive sensing.

### BACKGROUND

In conventional sensing, the sensor system sometimes oversamples the subject resulting in substantial amounts of data, at least some of which is redundant. The collection and processing of the redundant data may take more time and, as a result, is more expensive in terms of the sensing and processing resources that are consumed, and may be constrained by the resulting cost and the memory that may now allow high speed sampling rates. Alternatively, processing resources may be expended to eliminate at least some of the data.

Compressive sensing is a signal processing technique for efficiently acquiring and reconstructing a signal by solving undetermined linear systems. In contrast to conventional sensing techniques, compressive sensing may utilize only a few sensors and, as a result, may not completely sample the subject. However, in compressive sensing, the sparsity of a signal can be exploited to recover the signal from fewer samples than dictated by the Shannon-Nyquist sampling theorem that guides many conventional sensing systems. Examples of compressive sensing include compressive image sensing, such as video compressive sensing and hyper-spectral compressive sensing.

Due to hardware constraints, one property of at least some compressive imaging systems is that for multiple frames, there is only a single measurement available per pixel. For example, in video compressive sensing, high-speed frames are modulated at a higher frequency than the capture rate of the camera, which is operating at a relatively low frame rate. In this manner, each captured measurement frame can permit a number of high-speed frames to be reconstructed. These systems are termed snapshot compressive imaging systems in which a captured measurement frame serves as a snapshot of a plurality of higher-speed frames. Snapshot compressive sensing therefore refers to compressive imaging systems in which multiple frames are mapped into a single measurement frame. Each pixel in the measurement frame is a linear combination of the corresponding pixels in the frames that are combined together. However, traditional compressive sensing theory including the theoretical results for compressive sensing systems are generally inapplicable since these theoretical results are derived based upon the assumption that the sensing matrix is drawn from some random distributions.

### SUMMARY

A method, apparatus and computer program product are provided in order reconstruct a signal captured by a snapshot compressive sensing system. In one embodiment, the signal is reconstructed utilizing a progressive gradient descent technique. In another embodiment, the signal is reconstructed utilizing a Euclidian projection technique. In either embodiment, the signal may be reconstructed in an efficient and accurate manner. In addition, at least some embodiments reconstruct the signal in a computationally efficient manner, thereby conserving processing and/or memory resources.

In an example embodiment a method is provided for decompressing images captured by a compressive imaging system in conjunction with a compressive imaging application. The method comprises determining an estimation error e^{t} based on a difference between: (i) a measurement y captured by the compressive imaging system and (ii) a product of a sensing matrix H and a signal x^{t} that has been estimated. The method comprises determining a gradient descent s^{t+1} based on a sum of: (i) the signal x^{t} that has been estimated and (ii) a product of a step size μ, a vector formulation of the sensing matrix H^{T} and the estimation error e^{t}. The method comprises projecting the gradient descent s^{t+1} comprising applying a compression function f and a decompression function g to estimate the signal x^{t+1}. The method comprises iteratively repeating determining the estimation error e^{t}; determining the gradient descent s^{t+1} and projecting the gradient descent s^{t+1} to provide a reconstructed signal following a final iteration; and providing the reconstructed signal for display or storage.

In another example embodiment there is provided a method wherein projecting the gradient descent s^{t+1} comprises estimating the signal x^{t+1} as x^{t+1}=g(f(s^{t+1})).

In another example embodiment there is provided a method wherein iteratively repeating comprises iteratively repeating with the step size u until t satisfies a predefined value.

In another example embodiment there is provided a method further comprising determining the step size for one or more iterations based at least partly on a resulting measurement error.

In another example embodiment there is provided a method wherein the step size is predetermined.

In another example embodiment there is provided a method wherein the compressive imaging system comprises a plurality of measurement elements and the measurement y captured by two or more of the measurement elements is processed with the same step size.

In another example embodiment there is provided a method wherein providing the reconstructed signal for display or storage comprises providing the reconstructed signal in conjunction with a compressive spectral optical coherence tomography application.

In an example embodiment there is provided an apparatus configured to decompress images captured by a compressive imaging system in conjunction with a compressive imaging application. The apparatus comprises at least one processor and at least one memory including computer program code for one or more programs. The at least one memory and the computer program code are configured to, with the at least one processor, cause the apparatus at least to determine an estimation error e^{t} based on a difference between: (i) a measurement y captured by the compressive imaging system and (ii) a product of a sensing matrix H and a signal x^{t} that has been estimated. The at least one memory and the computer program code are configured to, with the at least one processor, cause the apparatus at least to determine a gradient descent s^{t+1} based on a sum of: (i) the signal x^{t} that has been estimated and (ii) a product of a step size μ, a vector formulation of the sensing matrix H^{T} and the estimation error e^{t}. The at least one memory and the computer program code are configured to, with the at least one processor, cause the apparatus at least to perform projecting the gradient descent s^{t+1} comprising applying a compression function f and decompression function g to estimate the signal x^{t+1}. The at least one memory and the computer program code are configured to, with the at least one processor, cause the apparatus at least to perform iteratively repeating: determining the estimation error e^{t}; determining the gradient descent s^{t+1} and projecting the gradient descent s^{t+1} to provide a reconstructed signal following a final iteration; and provide the reconstructed signal for display or storage.

In another example embodiment there is provided an apparatus wherein the at least one memory and the computer program code are configured to, with the at least one processor, cause the apparatus to perform projecting the gradient descent s^{t+1} comprising estimating the signal x^{t+1} as x^{t+1}=(g(f(s^{t+1})).

In another example embodiment there is provided an apparatus wherein the at least one memory and the computer program code are configured to, with the at least one processor, cause the apparatus to perform iteratively repeating with a step size n until t satisfies a predefined value.

In another example embodiment there is provided an apparatus wherein the at least one memory and the computer program code are further configured to, with the at least one processor, cause the apparatus to determine the step size for one or more iterations based at least partly on a resulting measurement error.

In another example embodiment there is provided an apparatus wherein the step size is predetermined.

In another example embodiment there is provided an apparatus wherein the compressive imaging system comprises a plurality of measurement elements and the measurement y captured by two or more measurement elements is processed with the same step size.

In another example embodiment there is provided an apparatus wherein the at least one memory and the computer program code are configured to, with the at least one processor, cause the apparatus to provide the reconstructed signal for display or storage in conjunction with a compressive spectral optical coherence tomography application.

In an example embodiment there is provided a computer program product configured to decompress images captured by a compressive imaging system in conjunction with a compressive imaging application. The computer program product comprises at least one non-transitory computer-readable storage medium having computer executable program code instructions stored therein. The computer executable program code instructions comprising program code instructions are configured, upon execution, at least to perform: determining an estimation error e^{t} based on a difference between: (i) a measurement y captured by the compressive imaging system and (ii) a product of a sensing matrix H and a signal x^{t} that has been estimated. The computer executable program code instructions comprising program code instructions are configured, upon execution, at least to perform: determining a gradient descent s^{t+1} based on a sum of: (i) the signal x^{t} that has been estimated and (ii) a product of a step size u, a vector formulation of the sensing matrix H^{T} and the estimation error e^{t}. The computer executable program code instructions comprising program code instructions are configured, upon execution, at least to perform: projecting the gradient descent s^{t+1} comprising applying a compression function f and a decompression function g to estimate the signal x^{t+1}. The computer executable program code instructions comprising program code instructions are configured, upon execution, at least to perform: iteratively repeating: determining the estimation error e^{t}; determining the gradient descent s^{t+1} and projecting the gradient descent s^{t+1} to provide a reconstructed signal following a final iteration; and providing the reconstructed signal for display or storage.

In another example embodiment there is provided a computer program product wherein the program code instructions configured to project the gradient descent s^{t+1} comprise program code instructions configured to estimate the signal x^{t+1} as x^{t+1}=(g(f(s^{t+1})).

In another example embodiment there is provided a computer program product wherein the program code instructions configured to iteratively repeat comprise program code instructions configured to iteratively repeat with a step size μ until t satisfies a predefined value.

In another example embodiment there is provided a computer program product wherein the computer executable program code instructions further comprise program code instructions configured, upon execution, to determine the step size for one or more iterations based at least partly on a resulting measurement error.

In another example embodiment there is provided a computer program product wherein the step size is predetermined.

In another example embodiment there is provided a computer program product wherein the compressive imaging system comprises a plurality of measurement elements and the measurement y captured by two or more of the measurement elements is processed with the same step size.

In another example embodiment there is provided a computer program product wherein the program code instructions configured to provide the reconstructed signal for display or storage comprise program code instructions configured to provide the reconstructed signal in conjunction with a compressive spectral optical coherence tomography application.

In an example embodiment a method is provided for decompressing images captured by a compressive imaging system in conjunction with a compressive imaging application. The method comprises determining an estimation error e^{t} based on a difference between: (i) a measurement y provided by the compressive imaging system and (ii) a product of a sensing matrix H and a signal x^{t} that has been estimated. The method comprises determining a Euclidian projection s^{t+1} based on a sum of: (i) the signal x^{t} that has been estimated and (ii) a product of a step size μ, a vector formulation of the sensing matrix H^{T}, an inverse of a matrix R⁻¹ defined by a product of the sensing matrix H and the vector formulation of the sensing matrix H^{T}, and the estimation error e^{t}. The method comprises projecting the Euclidian projection s^{t+1} comprising applying a compression function f and a decompression function g to estimate the signal x^{t+1}. The method comprises iteratively repeating: determining the estimation error e^{t}; determining the Euclidian projection s^{t+1} and projecting the Euclidian projection s^{t+1} to provide a reconstructed signal following a final iteration; and providing the reconstructed signal for display or storage.

In another example embodiment there is provided a method wherein projecting the Euclidian projection s^{t+1} comprises estimating the signal x^{t+1} as x^{t+1}=g(f(s^{t+1})).

In another example embodiment there is provided a method wherein iteratively repeating comprises iteratively repeating with the step size μ until t satisfies a predefined value.

In another example embodiment there is provided a method further comprising estimating the step size such that the step size changes for at least some iterations.

In another example embodiment there is provided a method wherein the compressive imaging system comprises a plurality of measurement elements and wherein the step size for a respective measurement element is predetermined for all iterations.

In another example embodiment there is provided a method wherein the compressive imaging system comprises a plurality of measurement elements and different step sizes are utilized in conjunction with processing of the measurement y captured by at least some of the measurement elements.

In another example embodiment there is provided a method wherein providing the reconstructed signal for display or storage comprises providing the reconstructed signal in conjunction with a compressive spectral optical coherence tomography application.

In an example embodiment there is provided an apparatus configured to decompress images captured by a compressive imaging system in conjunction with a compressive imaging application. The apparatus comprises at least one processor and at least one memory including computer program code for one or more programs. The at least one memory and the computer program code are configured to, with the at least one processor, cause the apparatus at least to perform: determining an estimation error e^{t} based on a difference between: (i) a measurement y provided by the compressive imaging system and (ii) a product of a sensing matrix H and a signal x^{t} that has been estimated. The at least one memory and the computer program code are configured to, with the at least one processor, cause the apparatus at least to perform: determining a Euclidian projection s^{t+1} based on a sum of: (i) the signal x^{t} that has been estimated and (ii) a product of a step size μ, a vector formulation of the sensing matrix H^{T}, an inverse of a matrix R⁻¹ defined by a product of the sensing matrix H and the vector formulation of the sensing matrix H^{T}, and the estimation error e^{t}. The at least one memory and the computer program code are configured to, with the at least one processor, cause the apparatus at least to perform: projecting the Euclidian projection s^{t+1} comprising applying compression a function f and a decompression function g to estimate the signal x^{t+1}. The at least one memory and the computer program code are configured to, with the at least one processor, cause the apparatus at least to perform: iteratively repeating: determining the estimation error e^{t}; determining the Euclidian projection s^{t+1} and projecting the Euclidian projection s^{t+1} to provide a reconstructed signal following a final iteration; and providing the reconstructed signal for display or storage.

In another example embodiment there is provided an apparatus wherein the at least one memory and the computer program code are configured to, with the at least one processor, cause the apparatus to perform projecting the Euclidian projection s^{t+1} comprising estimating the signal x^{t+1} as x^{t+1}=(g(f(s^{t+1})).

In another example embodiment there is provided an apparatus wherein the at least one memory and the computer program code are configured to, with the at least one processor, cause the apparatus to perform iteratively repeating with a step size n until t satisfies a predefined value.

In another example embodiment there is provided an apparatus wherein the at least one memory and the computer program code are further configured to, with the at least one processor, cause the apparatus to estimate the step size such that the step size changes for at least some iterations.

In another example embodiment there is provided an apparatus wherein the compressive imaging system comprises a plurality of measurement elements and wherein the step size for a respective measurement element is predetermined for all iterations.

In another example embodiment there is provided an apparatus wherein the compressive imaging system comprises a plurality of measurement elements and different step sizes are utilized in conjunction with processing of the measurement y captured by at least some of the measurement elements.

In another example embodiment there is provided an apparatus according to any one of wherein the at least one memory and the computer program code are configured to, with the at least one processor, cause the apparatus to provide the reconstructed signal for display or storage in conjunction with a compressive spectral optical coherence tomography application.

In an example embodiment there is provided a computer program product configured to decompress images captured by a compressive imaging system in conjunction with a compressive imaging application. The computer program product comprises at least one non-transitory computer-readable storage medium having computer executable program code instructions stored therein. The computer executable program code instructions comprising program code instructions are configured, upon execution, at least to perform: determining an estimation error e^{t} based on a difference between: (i) a measurement y provided by the compressive imaging system and (ii) a product of a sensing matrix H and a signal x^{t} that has been estimated. The computer executable program code instructions comprising program code instructions are configured, upon execution, at least to perform: determining a Euclidian projection s^{t+1} based on a sum of: (i) the signal x^{t} that has been estimated and (ii) a product of a step size μ, a vector formulation of the sensing matrix H^{T}, an inverse of a matrix R⁻¹ defined by a product of the sensing matrix H and the vector formulation of the sensing matrix H^{T}, and the estimation error e^{t}. The computer executable program code instructions comprising program code instructions are configured, upon execution, at least to perform: projecting the Euclidian projection s^{t+1} comprising applying a compression function f and a decompression function g to estimate the signal x^{t+1}. The computer executable program code instructions comprising program code instructions are configured, upon execution, at least to perform: iteratively repeating: determining the estimation error e^{t}; determining the Euclidian projection s^{t+1} and projecting the Euclidian projection s^{t+1} to provide a reconstructed signal following a final iteration; and providing the reconstructed signal for display or storage.

In another example embodiment there is provided a computer program product wherein the program code instructions configured to project the Euclidian projection s^{t+1} comprise program code instructions configured to estimate the signal x^{t+1} as x^{t+1}=(g(f(s^{t+1})).

In another example embodiment there is provided a computer program product wherein the program code instructions configured to iteratively repeat comprise program code instructions configured to iteratively repeat with a step size u until t satisfies a predefined value.

In another example embodiment there is provided a computer program product wherein the computer program instructions are further configured to estimate the step size such that the step size changes for at least some iterations.

In another example embodiment there is provided a computer program product wherein the compressive imaging system comprises a plurality of measurement elements and wherein the step size for a respective measurement element is predetermined for all iterations.

In another example embodiment there is provided a computer program product wherein the compressive imaging system comprises a plurality of measurement elements and different step sizes are utilized in conjunction with processing of the measurement y captured by at least some of the measurement elements.

In another example embodiment there is provided a computer program product wherein the program code instructions configured to provide the reconstructed signal for display or storage comprise program code instructions configured to provide the reconstructed signal in conjunction with a compressive spectral optical coherence tomography application.

In an example embodiment there is provided a method comprising: determining an estimation error e^{t} based on a difference between: (i) a measurement y captured by a compressive imaging system and (ii) a product of a sensing matrix H and a signal x^{t} that has been estimated. The method comprises determining a gradient descent s^{t+1} based on a sum of: (i) the signal x^{t} that has been estimated and (ii) a product of a step size u, a vector formulation of the sensing matrix H^{T} and the estimation error e^{t}. The method comprises projecting the gradient descent s^{t+1} comprising applying a compression function f and a decompression function g to estimate the signal x^{t+1}; iteratively repeating: determining the estimation error e^{t}; determining the gradient descent s^{t+1} and projecting the gradient descent s^{t+1} to provide a reconstructed signal following a final iteration; and providing the reconstructed signal for display or storage.

In another example embodiment there is provided a method wherein projecting the gradient descent s^{t+1} comprises estimating the signal x^{t+1} as x^{t+1}=g(f(s^{t+1})).

In another example embodiment there is provided a method wherein iteratively repeating comprises iteratively repeating with the step size n until t satisfies a predefined value.

In another example embodiment there is provided a method further comprising determining the step size for one or more iterations based at least partly on a resulting measurement error.

In another example embodiment there is provided a method wherein the step size is predetermined.

In another example embodiment there is provided a method wherein the compressive imaging system comprises a plurality of measurement elements and the measurement y captured by two or more of the measurement elements is processed with the same step size.

In another example embodiment there is provided a method wherein providing the reconstructed signal for display or storage comprises providing the reconstructed signal in conjunction with a compressive spectral optical coherence tomography application.

In an example embodiment there is provided an apparatus comprising means for: determining an estimation error e^{t} based on a difference between: (i) a measurement y captured by a compressive imaging system and (ii) a product of a sensing matrix H and a signal x^{t} that has been estimated. The apparatus comprises means for determining a gradient descent s^{t+1} based on a sum of: (i) the signal x^{t} that has been estimated and (ii) a product of a step size μ, a vector formulation of the sensing matrix H^{T} and the estimation error e^{t}. The apparatus comprises means for projecting the gradient descent s^{t+1} comprising applying a compression function f and a decompression function g to estimate the signal x^{t+1}. The apparatus comprises means for iteratively repeating: determining the estimation error e^{t}; determining the gradient descent s^{t+1} and projecting the gradient descent s^{t+1} to provide a reconstructed signal following a final iteration; and providing the reconstructed signal for display or storage.

In another example embodiment there is provided an apparatus wherein the means for projecting the gradient descent s^{t+1} comprises means for estimating the signal x^{t+1} as x^{t+1}=g(f(s^{t+1})).

In another example embodiment there is provided an apparatus wherein the means for iteratively repeating comprises means for iteratively repeating with a step size μ until t satisfies a predefined value.

In another example embodiment there is provided an apparatus wherein the means are configured to perform: determining the step size for one or more iterations based at least partly on a resulting measurement error.

In another example embodiment there is provided an apparatus wherein the step size is predetermined.

In another example embodiment there is provided an apparatus wherein the compressive imaging system comprises a plurality of measurement elements and the measurement y captured by two or more of the measurement elements is processed with the same step size.

In another example embodiment there is provided an apparatus wherein the means are configured to perform: providing the reconstructed signal for display or storage in conjunction with a compressive spectral optical coherence tomography application.

In an example embodiment there is provided a computer program comprising instructions for causing an apparatus to perform at least the following: determining an estimation error e^{t} based on a difference between: (i) a measurement y captured by a compressive imaging system and (ii) a product of a sensing matrix H and a signal x^{t} that has been estimated; determining a gradient descent s^{t+1} based on a sum of: (i) the signal x^{t} that has been estimated and (ii) a product of a step size u, a vector formulation of the sensing matrix H^{T} and the estimation error e^{t}; projecting the gradient descent s^{t+1} comprising applying a compression function f and decompression function g to estimate the signal x^{t+1}; iteratively repeating the determining the estimation error e^{t}; determining the gradient descent s^{t+1} and projecting the gradient descent s^{t+1} to provide a reconstructed signal following a final iteration; and providing the reconstructed signal for display or storage.

### BRIEF DESCRIPTION OF THE DRAWINGS

Having thus described certain example embodiments of the present disclosure in general terms, reference will hereinafter be made to the accompanying drawings, which are not necessarily drawn to scale, and wherein:

FIG. 1 is a block diagram of an apparatus that may be specifically configured in accordance with an example embodiment;

FIG. 2 is a graphical representation of snapshot compressive sensing;

FIG. 3 is a flowchart of the operations performed, such as by the apparatus of FIG. 1, in order to reconstruct a signal pursuant to snapshot compressive sensing in accordance with an example embodiment; and

FIG. 4 is a flowchart of the operations performed, such as by the apparatus of FIG. 1, in order to reconstruct a signal pursuant to snapshot compressive sensing in accordance with another example embodiment.

### DETAILED DESCRIPTION

Some embodiments of the present invention will now be described more fully hereinafter with reference to the accompanying drawings, in which some, but not all, embodiments of the invention are shown. Indeed, various embodiments of the invention may be embodied in many different forms and should not be construed as limited to the embodiments set forth herein; rather, these embodiments are provided so that this disclosure will satisfy applicable legal requirements. Like reference numerals refer to like elements throughout. As used herein, the terms “data,” “content,” “information,” and similar terms may be used interchangeably to refer to data capable of being transmitted, received and/or stored in accordance with embodiments of the present invention. Thus, use of any such terms should not be taken to limit the spirit and scope of embodiments of the present invention.

Additionally, as used herein, the term ‘circuitry’ may refer to one or more or all of the following: (a) hardware-only circuit implementations (such as implementations in analog circuitry and/or digital circuitry); (b) combinations of circuits and software, such as (as applicable): (i) a combination of analog and/or digital hardware circuit(s) with software/firmware and (ii) any portions of hardware processor(s) with software (including digital signal processor(s)), software, and memory(ies) that work together to cause an apparatus, such as a mobile phone or server, to perform various functions) and (c) hardware circuit(s) and/or processor(s), such as a microprocessor(s) or a portion of a microprocessor(s), that requires software (e.g., firmware) for operation, but the software may not be present when needed for operation. This definition of ‘circuitry’ applies to all uses of this term in this application, including in any claims. As a further example, as used in this application, the term ‘circuitry’ also covers an implementation of merely a hardware circuit or processor (or multiple processors) or portions of a hardware circuit or processor and its (or their) accompanying software and/or firmware. The term ‘circuitry’ also covers, for example and if applicable to the particular claim element, a baseband integrated circuit or processor integrated circuit for a mobile phone or a similar integrated circuit in a server, a cellular network device or other computing or network device.

As defined herein, a “computer-readable storage medium,” which refers to a physical storage medium (e.g., volatile or non-volatile memory device), may be differentiated from a “computer-readable transmission medium,” which refers to an electromagnetic signal.

A method, apparatus and computer program product are provided in order reconstruct a signal captured by a snapshot compressive sensing system. In some embodiments, the signal that is reconstructed may be a plurality of higher-speed frames that are represented by a single measurement frame that is captured by a snapshot compressive sensing system. The snapshot compressive sensing and the reconstruction of the signal may be employed in a variety of applications including various high dimensional compressive sensing applications, such as video compressive sensing, hyper-spectral compressive sensing, depth compressive sensing, polarization compressive sensing, compressive spectral optical coherence tomography, compressive hyperspectral video compressive sensing and/or joint video-depth compressive sensing.

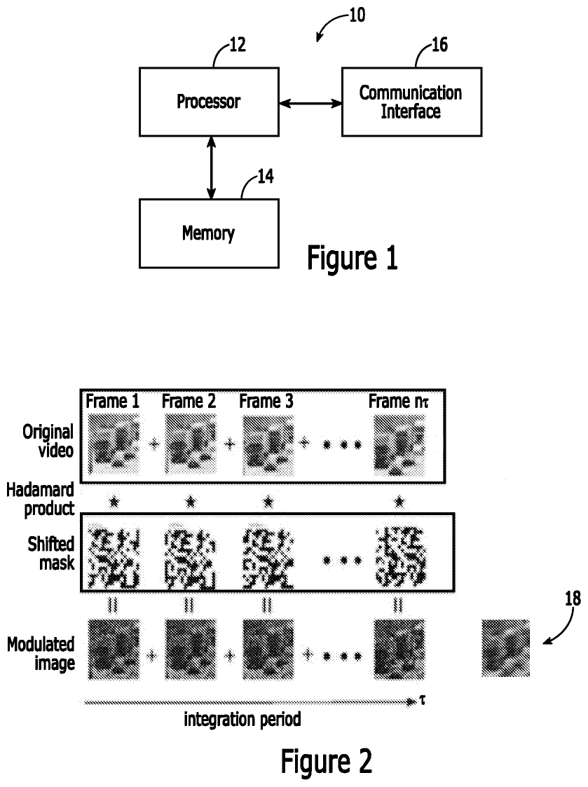

In order to reconstruct a signal subject to snapshot compressive sensing, an apparatus 10 is provided as shown, for example, in FIG. 1. The apparatus may be embodied by or in communication with any of a variety of different types of computing devices including, for example, a video processing system, an image processing system or any other system configured to decompress images captured by a snapshot compressive sensing system. As shown in FIG. 1, the apparatus of an example embodiment includes, is associated with or is otherwise in communication with a processor 12, an associated memory 14 and a communication interface 16.

The processor 12 (and/or co-processors or any other circuitry assisting or otherwise associated with the processor) may be in communication with the memory device 14 via a bus for passing information among components of the apparatus 10. The memory device may be non-transitory and may include, for example, one or more volatile and/or non-volatile memories. In other words, for example, the memory device may be an electronic storage device (e.g., a computer readable storage medium) comprising gates configured to store data (e.g., bits) that may be retrievable by a machine (e.g., a computing device like the processor). The memory device may be configured to store information, data, content, applications, instructions, or the like for enabling the apparatus to carry out various functions in accordance with an example embodiment of the present disclosure. For example, the memory device could be configured to buffer input data for processing by the processor. Additionally or alternatively, the memory device could be configured to store instructions for execution by the processor.

The apparatus 10 may, in some embodiments, be embodied in various computing devices as described above. However, in some embodiments, the apparatus may be embodied as a chip or chip set. In other words, the apparatus may comprise one or more physical packages (e.g., chips) including materials, components and/or wires on a structural assembly (e.g., a baseboard). The structural assembly may provide physical strength, conservation of size, and/or limitation of electrical interaction for component circuitry included thereon. The apparatus may therefore, in some cases, be configured to implement an embodiment of the present invention on a single chip or as a single “system on a chip.” As such, in some cases, a chip or chipset may constitute means for performing one or more operations for providing the functionalities described herein.

The processor 12 may be embodied in a number of different ways. For example, the processor may be embodied as one or more of various hardware processing means such as a coprocessor, a microprocessor, a controller, a digital signal processor (DSP), a processing element with or without an accompanying DSP, or various other circuitry including integrated circuits such as, for example, an ASIC (application specific integrated circuit), an FPGA (field programmable gate array), a microcontroller unit (MCU), a hardware accelerator, a special-purpose computer chip, or the like. As such, in some embodiments, the processor may include one or more processing cores configured to perform independently. A multi-core processor may enable multiprocessing within a single physical package. Additionally or alternatively, the processor may include one or more processors configured in tandem via the bus to enable independent execution of instructions, pipelining and/or multithreading.

In an example embodiment, the processor 12 may be configured to execute instructions stored in the memory device 14 or otherwise accessible to the processor. Alternatively or additionally, the processor may be configured to execute hard coded functionality. As such, whether configured by hardware or software methods, or by a combination thereof, the processor may represent an entity (e.g., physically embodied in circuitry) capable of performing operations according to an embodiment of the present disclosure while configured accordingly. Thus, for example, when the processor is embodied as an ASIC, FPGA or the like, the processor may be specifically configured hardware for conducting the operations described herein. Alternatively, as another example, when the processor is embodied as an executor of instructions, the instructions may specifically configure the processor to perform the algorithms and/or operations described herein when the instructions are executed. However, in some cases, the processor may be a processor of a specific device (e.g., an image processing system) configured to employ an embodiment of the present invention by further configuration of the processor by instructions for performing the algorithms and/or operations described herein. The processor may include, among other things, a clock, an arithmetic logic unit (ALU) and logic gates configured to support operation of the processor.

The communication interface 16 may be any means such as a device or circuitry embodied in either hardware or a combination of hardware and software that is configured to receive and/or transmit data, such as by receiving frames from a snapshot compressive sensing system or from an external memory device and/or for providing the reconstructed signal to an imaging system or other type of display for presentation or to an external memory device for storage. In this regard, the communication interface may include, for example, an antenna (or multiple antennas) and supporting hardware and/or software for enabling communications with a wireless communication network. Additionally or alternatively, the communication interface may include the circuitry for interacting with the antenna(s) to cause transmission of signals via the antenna(s) or to handle receipt of signals received via the antenna(s). In some environments, the communication interface may alternatively or also support wired communication. As such, for example, the communication interface may include a communication modem and/or other hardware/software for supporting communication via cable, digital subscriber line (DSL), universal serial bus (USB) or other mechanisms.

In traditional compressive sensing, the measurement system is usually modeled as

y=Φx+z, (1)

where ΦϵR^{m×n}, m<<n, denotes the sensing matrix, xϵRⁿ is the desired signal and zϵR^{m} denotes the noise. Stated another way the measurement system may be modeled as:

$$[ \begin{matrix}{y}_{1} \\ {y}_{2} \\ ⋮ \\ {y}_{M}\end{matrix} = [ \begin{matrix}\begin{matrix}{Φ}_{11} & {Φ}_{12} & … & {Φ}_{1 N - 1} & {Φ}_{N}\end{matrix} \\ \begin{matrix}{Φ}_{21} & {Φ}_{22} & … & {Φ}_{2 N - 1} & {Φ}_{2 N}\end{matrix} \\ \begin{matrix}⋮ & ⋮ & ⋱ & ⋮ & ⋮\end{matrix} \\ \begin{matrix}{Φ}_{M 1} & {Φ}_{M 2} & … & {Φ}_{MN - 1} & Φ \text{?}\end{matrix}\end{matrix} ] [ \begin{matrix}{x}_{1} \\ {x}_{2} \\ ⋮ \\ {x}_{N - 1} \\ {x}_{N}\end{matrix} ] \\ \text{?} \text{indicates text missing or illegible when filed}$$

For a k-sparse signal, e.g., ∥x∥₀≤k, if the sensing matrix satisfies the restricted isometry property (RIP) condition, m=(k log(n/k)) measurements are sufficient to recover the signal efficiently and robustly.

For example, a hyperspectral compressive imaging system, also known as a coded aperture snapshot spectral imaging (CASSI) system, recovers a three-dimensional (3D) spectral data cube, in which more than 30 frequency channels, that is, images, at different wavelengths have been reconstructed, from a single two-dimensional (2D) captured measurement.

The measurement in these hardware systems usually can be modeled as:

y=Hx+z, (2)

where H is the sensing matrix. Unlike traditional compressive sensing, the H matrix is not a dense matrix. In snapshot compressive sensing, the matrix H may have a structure that can be represented as:

H=[D₁, . . . ,D_{B}], (3)

where

$$\{ {D}_{k} \} \frac{B}{k} = 1$$

are diagonal matrices. As such, the measurement y may be represented as:

$$y = [ \begin{matrix}{y}_{n , η} \\ {y}_{n , η} \\ ⋮ \\ y \text{?}\end{matrix} ] = \underbrace{[ \begin{matrix}Φ \text{?} & 0 & … Φ \text{?} 0 … & … 0 Φ \text{?} & 0 … 0 \\ 0 & ⋱ & ⋱ & ⋱ & 0 \\ 0 & … 0 Φ & … 0 Φ \text{?} & … … 0 & Φ \text{?}\end{matrix} ]}_{Φ} \\ [ \begin{matrix}\begin{matrix}\begin{matrix}x \text{?} \\ ⋮\end{matrix} \\ x \text{?}\end{matrix} \} frame 1 \\ \begin{matrix}\begin{matrix}x \text{?} \\ ⋮\end{matrix} \\ x \text{?}\end{matrix} \} frame 2 \\ \begin{matrix}x \text{?} & ◯ \\ ⋮ & ◯ \\ x \text{?} & ◯\end{matrix} \\ \begin{matrix}\begin{matrix}x \text{?} \\ ⋮\end{matrix} \\ x \text{?}\end{matrix} \} frame {n}_{i}\end{matrix} ]$$

$$\text{?} \text{indicates text missing or illegible when filed}$$

Taking a video compressive sensing system as an example in which B high-speed frames {Xₖ}ₖ₌₁^{B}∈ [symbol] ⁿ^{ₓ}^{×n}^{_{y}} are modulated by the masks {Cₖ}ₖ₌₁^{B}∈ [symbol] ⁿ^{ₓ}^{×n}^{_{y}}, correspondingly, the measurement Y∈ [symbol] ⁿ^{ₓ}^{×n}^{_{y}} may be defined as:

Y=Σₖ₌₁^{B}Xₖ⊙Cₖ+Z. (4)

In this example, all B pixels located at position (i, j), i=1, . . . , nₓ; j=1, . . . , n_{y}, are measured together as

y_{i,j}=Σₖ₌₁^{B}c_{i,j,k}x_{i,j,k}+z_{i,j}. (5)

This can also be stated in the vector formulation of equation (2), by defining

x=[x₁^{T}, . . . ,x_{B}^{T}]^{T}, (6)

where xₖ=vec(Xₖ), and Dₖ=diag(vec(Cₖ)), for k=1, . . . , B. Thus x∈ [symbol] ⁿ^{ₓ}^{×n}^{_{y}}^{B}, H∈ [symbol] ⁿ^{ₓ}^{×n}^{_{y}}^{×(n}^{ₓ}ⁿ^{_{y}}^{B)} and the sampling rate in equation (2) is above equal to 1/B.

An example of snapshot compressive sensing is depicted in FIG. 2. As shown, the original video includes a plurality of frames designated Frame 1, Frame 2, . . . Frame nₜ. Each frame is subjected to one or more masks, such as taking the Hadamard product of a frame and a mask, e.g., a shifted mask that shifts between frames. The resulting modulated images for a single integration period are captured in a single snapshot, thereby forming a single measurement image 18.

Given the structure of the sensing matrix in equation (3), the foregoing analysis does not satisfy the RIP or mutual coherence conditions. Therefore, traditional compressive sensing theory based on random sampling does not apply to applications, such as snapshot compressive sensing, which are modeled as in accordance with equation (2).

In accordance with an example embodiment, a method, apparatus 10 and computer program product are provided to reconstruct a signal captured by a compressive sensing system, such as a snapshot compressive sensing system and, in one example, a snapshot compressive imaging system. In regards to data compression, data compression codes, such as lossy compression codes, are utilized.

A lossy compression code of rate r for a compact set [symbol] ⊂ [symbol] ⁿ is characterized by its encoding and decoding mappings (f, g), where f: Q→{1, 2, . . . , 2^{nr}}, and g: {1, 2, . . . , 2^{nr}}→Rⁿ. The codebook of this code is defined as C [symbol] {g(f(x)): x∈ [symbol] }. In this regard, |C|≤2^{nr}.

In addition to its rate r, the performance of the compression code defined by (f, g) is characterized by its distortion δ, where

$$δ {=}^{Δ} \frac{1}{n} {‖ x - g ( f ( x ) ) ‖}_{2}^{2} .$$

In an example embodiment relevant to the processing of multi-frame signals, such as videos, which consist of a sequence of image frames, a lossy compression code is defined for a sequence of frames as described below. In this regard, for a compact set [symbol] ⊂ [symbol] ^{nB}, each signal x∈ [symbol] , consists of B vectors (with each vector representing a frame) {x1, . . . , xB} in Rⁿ, with n=nₓn_{y} as shown in equation (6). A lossy compression code of rate r for [symbol] is characterized by its encoding mapping f, where

f: [symbol] →{1,2, . . . ,2^{nBr}}, (7)

and its decoding mapping g, where

g:{1,2, . . . ,2^{nBr}}→ [symbol] ^{nB}. (8)

The average distortion between x and its reconstruction x is defined as:

$$d ( x , \hat{x} ) {=}^{Δ} \frac{1}{nB} {\sum }_{i = 1}^{B} {‖ {x}_{i} - {\hat{x}}_{i} ‖}_{2} = \frac{1}{nB} {‖ {x}_{i} - \hat{x} ‖}_{2}^{2} , \qquad ( 9 )$$

in which x is defined as in equation (6). If

\tilde{x}=g(f(x)) (10)

the distortion of code (f,g) is denoted by δ, which is defined as the supremum of all achievable average per-frame distortions. Thus, the distortion δ is defined as:

$$δ {=}^{Δ} d ( x , \tilde{x} ) = \frac{1}{nB} {‖ x - \tilde{x} ‖}_{2}^{2} \qquad ( 11 )$$

In relation to compression-based recovery, the compact set [symbol] ⊂ [symbol] ^{nB} is equipped with a rate-r compression code described by mappings (f, g), defined in equations (7) and (8). C is the codebook of this code defined as:

C={g(f(x):x∈ [symbol] }. (12)

Since the code is of rate r, |C|≤2^{nBr}. For x∈ [symbol] its snapshot measurement is defined as:

y=Hx+z=Σᵢ₌₁^{B}Dᵢxᵢ+z, (13)

where Di=diag(Di1, . . . , Din).

A compressible signal pursuit (CSP)-type recovery method, given y and {Dᵢ}ᵢ₌₁^{B}, estimates x by solving the following optimization:

$$\hat{x} = arg {min}_{c ∈ 𝒞} {‖ y - {\sum }_{i = 1}^{B} {D}_{i} {c}_{i} ‖}_{2}^{2} , \qquad ( 14 )$$

where Cis defined in equation (12). In other words, given a measurement vector y, this optimization, among all compressible signals, that is, signals in the codebook, picks the signal that is closest to the observed measurements. An advantage of compression-based recovery methods such as set forth by equation (14) is that, without much additional effort, through the use of proper compression codes, compression-based recovery methods can take advantage of both temporal (spectral) and spatial dependencies that exist in multi-frame signals, such as videos. At B=1, with a traditional dense sensing matrix, this reduces to the standard CSP optimization. However, for B>1, the original CSP optimization does not work in the snapshot compressive sensing setting.

The performance of this CSP-type recovery method may be characterized by connecting the parameters of the code, its rate and its distortion, to the number of frames B and the reconstruction quality.

In an instance in which: (i)

$$∀ x ∈ , {‖ x ‖}_{∞} \leq \frac{ρ}{2} ,$$

(ii) the rate-r code achieves distortion δ on [symbol] (iii) for i=1, . . . , B, (iii) Di=diag(Di1, . . . , Din),

$${\{ {D}_{ij} \}}_{j = 1}^{n} {∼}^{i . i . d .} 𝒩 ( 0 , 1 ) , ( v ) ϵ > 0 \qquad ( iv )$$

and (vi)

$$ϵ \leq \frac{16}{3} \text{:}$$

$$\frac{1}{nB} {‖ x - \hat{x} ‖}_{2}^{2} \leq δ + {ρ}^{2} ϵ \qquad ( 15 )$$

with a probability larger than

$$1 - {2}^{nBr + 1} {e}^{- \frac{{ɛ}^{2} n}{{iGK}^{2}}} ,$$

where K=8/3. Given the same preconditions as those set forth above with respect to equation (15) and in an instance in which η>0 and B is defined as:

$$B < \frac{1}{η} ( \frac{log \frac{1}{δ}}{2 r} ) \qquad ( 16 )$$

Then,

$$Pr ( \frac{1}{nB} {‖ x - \hat{x} ‖}_{2}^{2} > δ + 8 {ρ}^{2} \sqrt{\frac{log \frac{1}{δ}}{η}} ) \leq 2 {e}^{- \frac{log \frac{1}{δ}}{ η} n} \qquad ( 17 )$$

The relationship set forth in equation (15) may be proved by letting

$$ϵ = 8 \sqrt{\frac{log \frac{1}{δ}}{η}} .$$

Then, according to equation (15), the probability of the error event is upper bounded by:

$${2}^{nBr + 1} {e}^{- \frac{{ϵ}^{2} n}{18 {K}^{2}}} \leq 2 {exp}^{- \frac{n}{η} log \frac{1}{δ} ( \frac{4}{{K}^{2}} - \frac{ln 2}{2} )} \qquad ( 18 )$$

in which K=8/3. But,

$$\frac{4}{{K}^{2}} - \frac{ln 2}{2} > \frac{1}{5}$$

such mat me desired result follows.

To understand the implications of equation (15) and its corollary expressed by equation (17), a family of compression codes {(fᵣ,gᵣ)}ᵣ for set [symbol] ⊂ [symbol] ^{nB}, indexed by their rate r are considered. The deterministic distortion-rate function of this family of codes is defined as

$$δ ( r ) = {sup}_{x ∈ Q} \frac{1}{nB} {‖ x - {g}_{r} ( {f}_{r} ( x ) ) ‖}_{2}^{2} .$$

The corresponding deterministic rate-distortion function of this family of codes is defined as:

r(δ)=inf{r:δ(r)≤δ}.

The α-dimension of this family of codes is defined as:

$$α = lim {sup}_{δ -> 0} \frac{2 r ( δ )}{log \frac{1}{δ}} \qquad ( 19 )$$

In the case of B=1, the α-dimension of a compression code essentially characterizes the minimum sampling rate required for CSP (in traditional compressive sensing) to asymptotically generate zero-distortion output. In snapshot compressive sensing, the sampling rate is

$$\frac{1}{B} .$$

Hence, for small values of δ, the result of equation (17) states that if the sampling rate exceeds ηα, the achieved distortion is bounded by a function of {δ, η, ρ}, where η is a free parameter.

In an instance in which each x∈ [symbol] consists of B frames, such that the first frame is a k-sparse signal with an l₂-norm bounded by 1, the next B−1 frames are built by moving the locations of the non-zero entries of the first frame. This model is premised upon the relatedness of consecutive video frames. For the first frame, by describing the locations of the non-zero entries and quantizing the non-zero entries, a lossy compression code may be constructed. Since all frames share the same non-zero values, a code for all frames can be built by coding the locations of the non-zero entries of all B frames. The α-dimension of the code developed for the first frame is equal to

$$\frac{k}{n} .$$

For the new code, the locations of the non-zero entries do not depend on depend on δ, since as δ→0, its effect becomes negligible. Therefore, the α-dimension of the overall code for multi-frame signals is equal to

$$\frac{k}{nB} .$$

As described above, CSP optimization applied to a snapshot compressive sensing system is able to recover the signal, as long as, depending upon the α-dimension, the number of blocks B is small enough. However, CSP optimization is a non-convex optimization problem and solving such a problem through a search over the codebook is infeasible, even for small values of block length.

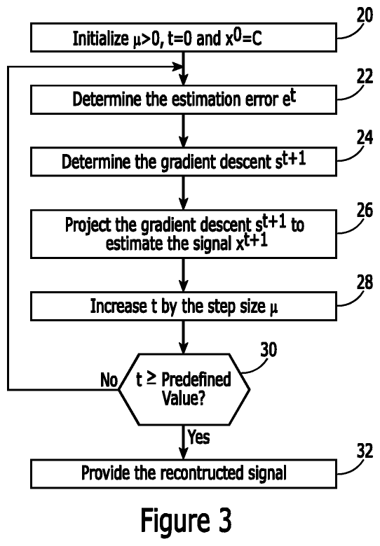

In accordance with an example embodiment, a compression-based projected gradient descent (PGD) technique for signal reconstruction in a snapshot compressive sensing system is provided. As shown in FIG. 3 and given H and y, the apparatus 10 of this example embodiment includes means, such as processing circuitry, the processor 12 or the like, for initializing u>0 and setting x⁰ to 0. See block 20 of FIG. 3. The apparatus then performs an iterative process to determine x with t=0 during the initial iteration. The apparatus of this example embodiment therefore includes means, such as the processing circuitry, the processor or the like, for determining the estimation error e^{t}. See block 22. The estimation error e^{t} is determined based upon a difference between: (i) a measurement y captured by a compressive imaging system and (ii) a product of a sensing matrix H and a signal x^{t} that has been estimated during the prior iteration (or that is set to a predefined value, e.g., x⁰=0 during the initial iteration). In one embodiment, the estimation error e^{t} is determined as follows:

e^{t}=y−Hx^{t} (21)

During each iteration, the apparatus 10 of this example embodiment also includes means, such as the processing circuitry, the processor 12 or the like, for means for determining the gradient descent s^{t+1}. See block 24. The gradient descent s^{t+1} is determined based upon a sum of: (i) the signal x^{t} that has been estimated and (ii) a product of a step size μ, a vector formulation of the sensing matrix H^{T} and the estimation error e^{t}. In one embodiment the gradient descent s^{t+1} is determined as follows:

s^{t+1}=x^{t}+μH^{T}e^{t} (22)

Also during each iteration, the apparatus 10 of this example embodiment also includes means, such as the processing circuitry, the processor 12 or the like, for means for projecting the gradient descent s^{t+1} to estimate the signal x^{t+1}. See block 26. The gradient descent s^{t+1} is projected by applying compression function f and decompression function g to estimate the signal x^{t+1}. In one embodiment, projection of the signal x^{t+1} is determined as follows:

x^{t+1}=g(f(s^{t+1})) (23)

The apparatus 10 of this example embodiment also includes means, such as the processing circuitry, the processor 12 or the like, for incrementing the value oft by the step size u and then comparing the value oft to a predefined value. See blocks 28 and 30 of FIG. 3. In an instance in which t does not satisfy the predefined value, such as by being less than the predefined value, the foregoing process is iteratively repeated. In this regard, the apparatus of this example embodiment includes means, such as the processing circuitry, the processor or the like, for iteratively repeating the determination the estimation error e^{t} in block 22, the determination of the gradient descent s^{t+1} in block 24 and the projection of the gradient descent s^{t+1} in block 26. Once the iterations have been completed, such as by a determination that t satisfies the predefined value, such as by equaling or exceeding the predefined value, the reconstructed signal is provided. As such, the apparatus of this example embodiment includes means, such as the processing circuitry, the processor or the like, for providing the reconstructed signal, such as for display by an imaging system, video playback system, etc., storage or the like. See block 32.

In an example embodiment, the step size for one or more iterations, such as for each of the plurality of iterations, is determined based at least partly on the resulting measurement error as described below. Alternatively, the step size may be predetermined.

By way of example of the PGD technique, a compact set [symbol] ⊂ [symbol] ^{nB} is provided, such that for all x∈ [symbol] ,

$${‖ x ‖}_{∞} \leq \frac{ρ}{2} .$$

Furthermore, a compression code for set Q is provided with encoding and decoding mappings, f and g, respectively, with the code operating at rate r and distortion δ. For x∈Q, x̅=g(f(x)), x being measured as y=Σᵢ₌₁^{B}D, xᵢ, Di=diag(Di1, . . . , Din),

$${D}_{ij} {\sim}^{1.1 . d} 𝒩 ( 0 , 1 ) ,$$

x^{t} denoting the output of PGD technique at iteration t with μ=1 and λ∈(0,0.5), then for t=0,1, . . . , as long as,

$$\frac{1}{nB} {‖ \tilde{x} - {x}^{t} ‖}_{2}^{2} \geq δ$$

it follows that:

$$\frac{1}{\sqrt{nB}} {‖ {x}^{t + 1} - \tilde{x} ‖}_{2} \leq \frac{2 λ}{\sqrt{nB}} {‖ {x}^{i} - \tilde{x} ‖}_{2} + 4 \sqrt{δ} \qquad ( 24 )$$

with a probability at least

$$1 - {2}^{4 nBr} {e}^{- {( \frac{\text{?} \text{?}}{16 {ρ}^{2}} )}^{2} {λ}^{2} n} - ( {2}^{2 nBr} + 1 ) {e}^{- {n ( \frac{\text{?} \text{?}}{16 {ρ}^{2}} )}^{2}} \\ \text{?} \text{indicates text missing or illegible when filed} \qquad ( 25 )$$

The foregoing example demonstrates that the recovered signal by PGD will converge to \tilde{x}, which is the decoded version of the ground truth signal x using the encoding and decoding mappings, (f, g). In the foregoing example, the requirement that

$$\frac{1}{nB} {‖ x - {x}^{t} ‖}_{2}^{2} \geq δ$$

is not a restrictive assumption, as the error introduced by the compression code is δ. By using a lossy compression code with distortion δ, the final distortion will therefore be larger than δ. Finally, as noted above, the step-size is set to μ=1. However, other step-sizes may be utilized in other embodiments and, in some embodiments, the step-size may be modified from one iteration to another.

In another example embodiment, a fixed step-size technique in the form of a generalized alternating projection is provided for signal reconstruction in a snapshot compressive sensing system. In this regard, in order to avoid modifications to the step size μ and the impact upon the performance brought about by modifications to the step size μ and due to the special structure of the sensing matrix, that is, HH^{T} is a diagonal matrix, a compression-based GAP recovery algorithm for snapshot compressive sensing is set forth provided below in conjunction with this example embodiment. As before in which H=[D₁, . . . , D_{B}], and Di=diag(Dᵢ₁, . . . , Dᵢₙ) denoting the sensing matrix, matrix R is defined as follows:

R=HH^{T}=diag(R₁, . . . ,Rₙ), (26)

where Rⱼ=Σᵢ₌₁^{B}Dᵢⱼ², ∀j=1, . . . , n.

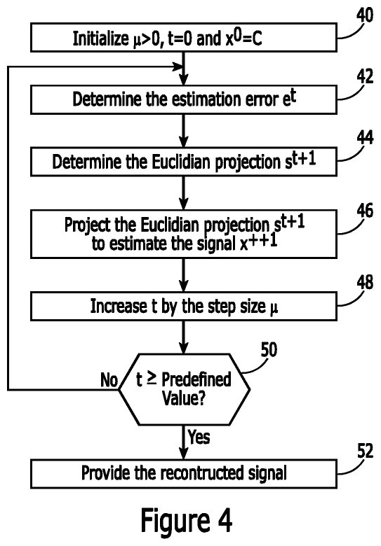

As shown in FIG. 4 and given H and y, the apparatus 10 of this example embodiment includes means, such as processing circuitry, the processor 12 or the like, for initializing u>0 and setting x⁰ to 0. See block 40. The apparatus then performs an iterative process to determine x with t=0 during the initial iteration. The apparatus of this example embodiment therefore includes means, such as the processing circuitry, the processor or the like, for determining the estimation error e^{t}. See block 42. The estimation error e^{t} is determined based upon a difference between: (i) a measurement y captured by a compressive imaging system and (ii) a product of a sensing matrix H and a signal x^{t} that has been estimated during the prior iteration (or that is set to a predefined value, e.g., x⁰=0 during the initial iteration). In one embodiment, the estimation error e^{t} is determined as follows:

e^{t}=y−Hx^{t} (27)

During each iteration, the apparatus 10 of this example embodiment also includes means, such as the processing circuitry, the processor 12 or the like, for means for determining the Euclidian projection s^{t+1}. See block 44. The Euclidian projection s^{t+1} is determined based upon a sum of: (i) the signal x^{t} that has been estimated and (ii) a product of a step size μ, a vector formulation of the sensing matrix H^{T}, an inverse of a matrix R⁻¹ defined by a product of the sensing matrix H and the vector formulation of the sensing matrix H^{T}, and the estimation error e^{t}. In one embodiment the Euclidian projection s^{t+1} is determined as follows:

e^{t}=y−Hx^{t} (28)

Also during each iteration, the apparatus 10 of this example embodiment also includes means, such as the processing circuitry, the processor 12 or the like, for projecting the Euclidian projection s^{t+1} to estimate the signal x^{t+1}. See block 46. The Euclidian projection s^{t+1} is projected by applying compression function f and decompression function g to estimate the signal x^{t+}. In one embodiment, projection of the signal x^{t+1} is determined as follows:

x^{t+1}=g(f(s^{t+1})) (29)

The apparatus 10 of this example embodiment also includes means, such as the processing circuitry, the processor 12 or the like, for modifying the value oft by the step size μ and then comparing the value oft to a predefined value. See blocks 48 and 50. In an instance in which t does not satisfy the predefined value, such as by being less than the predefined value, the foregoing process is iteratively repeated. In this regard, the apparatus of this example embodiment includes means, such as the processing circuitry, the processor or the like, for iteratively repeating the determination of the estimation error e^{t} of block 42, the determination of the Euclidian projection s^{t+1} of block 44 and the projection of the Euclidian projection s^{t+1} of block 46. Once the iterations have been completed, such as by a determination that t satisfied the predefined value, such as by equaling or exceeding the predefined value, the reconstructed signal is provided. As such, the apparatus of this example embodiment includes means, such as the processing circuitry, the processor or the like, for providing the reconstructed signal, such as for display by an imaging system, video playback system, etc., storage or the like. See block 52.

In an example embodiment, the step size for one or more iterations, such as for each of the plurality of iterations, is estimated, such as described below in conjunction with equation (32), such that the step size changes for at least some iterations. Alternatively, the step size may be predetermined as noted below.

The generalized alternating projection can be computed element-wise and, as such, offers technical advantages by being computationally efficient and conserving processing resources. Moreover, during the implementation of one example embodiment, {Dᵢ}ᵢ₌₁^{B} and R, need not be stored, thereby saving time and memory and increasing efficiency. Instead, only the diagonal elements of {Dᵢ}ᵢ₌₁^{B} and R need be stored in this example embodiment.

As shown below, the result of the foregoing compression-based GAP technique converges. In this regard and with the same preconditions as set forth above with respect to the example of the PGD technique that resulted in equations (24) and (25), for t=0, 1, . . . , s^{t+1}=x^{t}±BH^{T}R⁻¹(y−Hx^{t}), x^{t+1}=g(f(s^{t+1})), R being defined as in equation (26) and λ∈(0, 0.5), as long as

$$\frac{1}{nB} {‖ \tilde{x} - {x}^{t} ‖}_{2}^{2} \geq δ ,$$

it follows that:

$$\frac{1}{\sqrt{nB}} {‖ {x}^{t + 1} - \tilde{x} ‖}_{2} \leq \frac{2 λ}{\sqrt{nB}} {‖ {x}^{t} - \tilde{x} ‖}_{2} + 4 \sqrt{δ} , \qquad ( 30 )$$

with a probability at least

$$1 - {2}^{4 nBr} {e}^{- \frac{{λ}^{2} {δ}^{2} n}{2 B {ρ}^{\text{?}}}} - {2}^{2 nBr} {e}^{\frac{n δ}{2 {ρ}^{2} {B}^{2}}} \\ \text{?} \text{indicates text missing or illegible when filed} \qquad ( 31 )$$

The foregoing examples demonstrate that the GAP and PGD techniques have similar convergence behaviors. Moreover, both techniques result is the following: for a fixed λ>0, the resulting equations (25) and (31) bound the number of frames (B) that can be combined together, and still be recovered by the PGD technique and the GAP technique, respectively, as a function of λ, δ, r, and ρ. As noted above, the GAP technique converges when μ=B. In some embodiments, however, μ∈{1, 2} for the GAP technique. In contrast, in one embodiment of the PGD technique, the fixed step size μ may be defined as μ=2/B.

The foregoing embodiments utilizing PGD and GAP techniques for video compressive sensing compare favorably in terms of simulations performed in MATLAB with other techniques, namely, a Gaussian mixture model (GMM) technique proposed by Yang, et al. in articles entitled “Video compressive sensing by learning a Gaussian mixture model from measurements”, IEEE Transaction on Image Processing, 24(1):106-119 (January 2015) and “Video compressive sensing using Gaussian mixture models”, IEEE Transaction on Image Processing, 23(11):4863-4878 (November 2014), a GAP-wavelet-tree technique proposed by Yuan et al., in an article entitled “Low-cost compressive sensing for color video and depth, IEEE Conference on Computer Vision and Pattern Recognition (CVPR (2014) and a GAP-TV technique proposed by Yuan in an article entitled “Generalized alternating projection based total variation minimization for compressive sensing”, 2016 IEEE International Conference on Image Processing (ICIP), pp. 2539-2543 (September 2016).

Following the set up described by the aforementioned Yang article from 2014, the simulations utilized a video frame size of 256×256 pixels. B=8 video frames were modulated and collapsed into a single 256×256 snapshot compressive sensing measurement. There were a total of 32 frames and thus 4 measured frames were available. For each measured frame, given the masks, that is, the sensing matrices {Dᵢ}ᵢ₌₁^{B}, which are generated once and used in all the techniques, the task is to reconstruct the eight video frames. The movie picture experts group (MPEG) video compression method was used in the PGD technique of an example embodiment with the resulting performance of the PGD technique being termed “PGD-MPEG”. Different initialization approaches were used in conjunction with the PGD technique of an example embodiment including “PGD-MPEG (init. 0)” denoting initialization with zeros, “PGD-MPEG (init. TV)” signifying the GAP-TV results were used as initialization, and “PGD-MPEG (init. GAPw)” using the GAP-wavelet-tree results for initialization.

Even when initializing with zeros, the performance of PGD-MPEG is comparable with GMM, GMM-LR and GMM-FR (Yang et al., 2015). When initializing with the results of other algorithms, such as total variation (TV) or GAP. PGD-MPEG of an example embodiment can increase the peak signal-to-noise ratio (PSNR) up by more than 0.3 dB.

While the GMM-based algorithms are usually relatively slow, GAP-TV of an example embodiment provides results in a few seconds. As such, the PGD technique may be initialized by the results of the GAP-TV results.

In accordance with an example embodiment of the PGD technique, the step-size utilized during each iteration may be evaluated in relation to the resulting measurement error. Specifically, if μₜ denotes the step-size at the t^{th} iteration of the PGD technique, μₜ may be estimated as follows

$${μ}_{t} = arg {min}_{μ} {‖ y - H [ g ( f ( {x}^{t} + μ {H}^{⊤} ( y - {Hx}^{i} ) ) ) ) ‖}_{2} \qquad ( 32 )$$

In this way, the next estimate is moved as close as possible to the manifold [symbol] ={ξ|y=Hξ}. Derivative-free methods, such as described by Nelder & Mead in an article entitled “A simplex method for function minimization” in the Computer Journal, 7:308-313 (1965), may be utilized to solve this optimization problem. In an example embodiment, the results of the (fixed step size) GAP and (step size optimized) PGD techniques converge to a similar level within 100 iterations. Since no step-size search is required by the GAP technique, one iteration of an example embodiment of the GAP technique takes 0.09 seconds, which is faster, such as more than 280 times faster, an example embodiment of the PGD technique, which searches for the optimum step-size.

The results of a GAP technique of an example embodiment in which the step-size is fixed at μ=1 or μ=2 were better in terms of obtaining a greater PSNR than embodiments of the PGD technique in which μ=0.25 and μ=0.3 and also better than a PGD technique that optimizes the step size by searching between iterations. Since the GAP technique employs a different step-size on each measurement element by {Rᵢ}ᵢ₌₁ⁿ even when using the same μ, while the PGD technique of one embodiment shown in FIG. 8 searches for the optimum step size for all measurement elements, the convergence rate of the GAP technique may be faster than the PGD technique in at least some instances.

As described above, a method, apparatus 10 and computer program product are provided in accordance with an example embodiment for reconstructing a signal in accordance with snapshot compressive sensing utilizing a PGD or GAP technique. Snapshot compressive sensing and, as a result, the method, apparatus and computer program product of an example embodiment may be utilized in many different compressive imaging applications, including videos, hyperspectral images and 3D scene compressive imaging. In these applications, multiple signal frames are combined with each other, such that elements with the same (spatial, physical, etc.) locations are linearly combined together to form the measured signal frame. Therefore, the measured frame has the same dimensions of a single signal frame. In accordance with an example embodiment, GAP and PGD techniques may be utilized to efficiently recover and reconstruct a high dimensional signal from its snapshot measurements. The GAP and PGD techniques are compression-based recovery techniques that converge to the desired solution.

As described above, FIGS. 3 and 4 are flowcharts of an apparatus 10, method, and computer program product according to certain example embodiments. It will be understood that each block of the flowcharts, and combinations of blocks in the flowcharts, may be implemented by various means, such as hardware, firmware, processor, circuitry, and/or other devices associated with execution of software including one or more computer program instructions. For example, one or more of the procedures described above may be embodied by computer program instructions. In this regard, the computer program instructions which embody the procedures described above may be stored by a memory device 14 of an apparatus employing an embodiment of the present invention and executed by processing circuitry or a processor 12 of the apparatus. As will be appreciated, any such computer program instructions may be loaded onto a computer or other programmable apparatus (e.g., hardware) to produce a machine, such that the resulting computer or other programmable apparatus implements the functions specified in the flowchart blocks. These computer program instructions may also be stored in a computer-readable memory that may direct a computer or other programmable apparatus to function in a particular manner, such that the instructions stored in the computer-readable memory produce an article of manufacture, the execution of which implements the function specified in the flowchart blocks. The computer program instructions may also be loaded onto a computer or other programmable apparatus to cause a series of operations to be performed on the computer or other programmable apparatus to produce a computer-implemented process such that the instructions which execute on the computer or other programmable apparatus provide operations for implementing the functions specified in the flowchart blocks.

A computer program product is therefore defined in those instances in which the computer program instructions, such as computer-readable program code portions, are stored by at least one non-transitory computer-readable storage medium with the computer program instructions, such as the computer-readable program code portions, being configured, upon execution, to perform the functions described above, such as in conjunction with the flowcharts of FIGS. 3 and 4. In other embodiments, the computer program instructions, such as the computer-readable program code portions, need not be stored or otherwise embodied by a non-transitory computer-readable storage medium, but may, instead, be embodied by a transitory medium with the computer program instructions, such as the computer-readable program code portions, still being configured, upon execution, to perform the functions described above.

Accordingly, blocks of the flowcharts support combinations of means for performing the specified functions and combinations of operations for performing the specified functions for performing the specified functions. It will also be understood that one or more blocks of the flowcharts, and combinations of blocks in the flowcharts, may be implemented by special purpose hardware-based computer systems which perform the specified functions, or combinations of special purpose hardware and computer instructions.

In some embodiments, certain ones of the operations above may be modified or further amplified. Furthermore, in some embodiments, additional optional operations may be included. Modifications, additions, or amplifications to the operations above may be performed in any order and in any combination.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. A method for decompressing images captured by a compressive imaging system in conjunction with a compressive imaging application, the method comprising:
determining an estimation error e^{t} based on a difference between: (i) a measurement y captured by the compressive imaging system and (ii) a product of a sensing matrix H and a signal x^{t} that has been estimated;
determining a gradient descent s^{t+1} based on a sum of: (i) the signal x^{t} that has been estimated and (ii) a product of a step size μ, a vector formulation of the sensing matrix H^{T} and the estimation error e^{t};
projecting the gradient descent s^{t+1} comprising applying a compression function f and a decompression function g to estimate the signal x^{t+1};
iteratively repeating: determining the estimation error e^{t}; determining the gradient descent s^{t+1} and projecting the gradient descent s^{t+1} to provide a reconstructed signal following a final iteration; and
providing the reconstructed signal for display or storage.

2. A method according to claim 1 wherein projecting the gradient descent s^{t+1} comprises estimating the signal x^{t+1} as x^{t+1}=g(f(s^{t+1})).

3. (canceled)

4. A method according to claim 1 further comprising determining the step size for one or more iterations based at least partly on a resulting measurement error.

5. A method according to claim 1 wherein the step size is predetermined.

6. A method according to claim 1 wherein the compressive imaging system comprises a plurality of measurement elements and the measurement y captured by two or more of the measurement elements is processed with the same step size.

7. A method according to claim 1 wherein providing the reconstructed signal for display or storage comprises providing the reconstructed signal in conjunction with a compressive spectral optical coherence tomography application.

8. An apparatus configured to decompress images captured by a compressive imaging system in conjunction with a compressive imaging application, the apparatus comprising at least one processor and at least one memory including computer program code for one or more programs, the at least one memory and the computer program code configured to, with the at least one processor, cause the apparatus at least to perform:
determining an estimation error e^{t} based on a difference between: (i) a measurement y captured by the compressive imaging system and (ii) a product of a sensing matrix H and a signal x^{t} that has been estimated;
determining a gradient descent s^{t+1} based on a sum of: (i) the signal x^{t} that has been estimated and (ii) a product of a step size μ, a vector formulation of the sensing matrix H^{T} and the estimation error e^{t};
projecting the gradient descent s^{t+1} comprising applying a compression function f and decompression function g to estimate the signal x^{t+1};
iteratively repeating: determining the estimation error e^{t}; determining the gradient descent s^{t+1} and projecting the gradient descent s^{t+1} to provide a reconstructed signal following a final iteration; and
providing the reconstructed signal for display or storage.

9. An apparatus according to claim 8 wherein the at least one memory and the computer program code are configured to, with the at least one processor, cause the apparatus to perform projecting the gradient descent s^{t+1} comprising estimating the signal x^{t+1} as x^{t+1}=g(f(s^{t+1})).

10. (canceled)

11. An apparatus according to claim 8 wherein the at least one memory and the computer program code are further configured to, with the at least one processor, cause the apparatus to determine the step size for one or more iterations based at least partly on a resulting measurement error.

12. An apparatus according to claim 8 wherein the step size is predetermined.

13. An apparatus according to claim 8 wherein the compressive imaging system comprises a plurality of measurement elements and the measurement y captured by two or more of the measurement elements is processed with the same step size.

14. An apparatus according to claim 8 wherein the at least one memory and the computer program code are configured to, with the at least one processor, cause the apparatus to provide the reconstructed signal for display or storage in conjunction with a compressive spectral optical coherence tomography application.

15. A computer program product comprising at least one non-transitory computer-readable storage medium having computer executable program code instructions stored therein, the computer executable program code instructions comprising program code instructions configured, upon execution, at least to perform the method of claim 1.

16. (canceled)

17. (canceled)

18. (canceled)

19. A computer program product according to claim 15 wherein the step size is predetermined.

20. A computer program product according to claim 15 wherein the compressive imaging system comprises a plurality of measurement elements and the measurement y captured by two or more of the measurement elements is processed with the same step size.

21. (canceled)

22. A method for decompressing images captured by a compressive imaging system in conjunction with a compressive imaging application, the method comprising:
determining an estimation error e^{t} based on a difference between: (i) a measurement y provided by the compressive imaging system and (ii) a product of a sensing matrix H and a signal x^{t} that has been estimated;
determining a Euclidian projection s^{t+1} based on a sum of: (i) the signal x^{t} that has been estimated and (ii) a product of a step size μ, a vector formulation of the sensing matrix H^{T}, an inverse of a matrix R⁻¹ defined by a product of the sensing matrix H and the vector formulation of the sensing matrix H^{T}, and the estimation error e^{t};
projecting the Euclidian projection s^{t+1} comprising applying a compression function f and a decompression function g to estimate the signal x^{t+1};
iteratively repeating: determining the estimation error e^{t}; determining the Euclidian projection s^{t+1} and projecting the Euclidian projection s^{t+1} to provide a reconstructed signal following a final iteration; and
providing the reconstructed signal for display or storage.

23. (canceled)

24. (canceled)

25. A method according to claim 22 further comprising estimating the step size such that the step size changes for at least some iterations.

26. (canceled)

27. (canceled)

28. (canceled)

29. An apparatus configured to decompress images captured by a compressive imaging system in conjunction with a compressive imaging application, the apparatus comprising at least one processor and at least one memory including computer program code for one or more programs, the at least one memory and the computer program code configured to, with the at least one processor, cause the apparatus at least to perform:
determining an estimation error e^{t} based on a difference between: (i) a measurement y provided by the compressive imaging system and (ii) a product of a sensing matrix H and a signal x^{t} that has been estimated;
determining a Euclidian projection s^{t+1} based on a sum of: (i) the signal x^{t} that has been estimated and (ii) a product of a step size μ, a vector formulation of the sensing matrix H^{T}, an inverse of a matrix R⁻¹ defined by a product of the sensing matrix H and the vector formulation of the sensing matrix H^{T}, and the estimation error e^{t};
projecting the Euclidian projection s^{t+1} comprising applying compression a function f and a decompression function g to estimate the signal x^{t+1};
iteratively repeating: determining the estimation error e^{t}; determining the Euclidian projection s^{t+1} and projecting the Euclidian projection s^{t+1} to provide a reconstructed signal following a final iteration; and
providing the reconstructed signal for display or storage.

30. (canceled)

31. (canceled)

32. An apparatus according to claim 29 wherein the at least one memory and the computer program code are further configured to, with the at least one processor, cause the apparatus to estimate the step size such that the step size changes for at least some iterations.

33. (canceled)

34. (canceled)

35. (canceled)

36. A computer program product comprising at least one non-transitory computer-readable storage medium having computer executable program code instructions stored therein, the computer executable program code instructions comprising program code instructions configured, upon execution, at least to perform the method of claim 22.

37. (canceled)

38. (canceled)

39. (canceled)

40. (canceled)

41. (canceled)

42. (canceled)
